(19) United States
(12) Patent Application Publication
(10) Pub. No.: US 2026/0110085 A1
(43) Pub. Date: Apr. 23, 2026

(54) VENTING SLIT VALVE

(71) Applicant: Applied Materials, Inc., Santa Clara, CA (US)

(72) Inventors: Ofer Amir, Santa Barbara, CA (US); Prodosh Kumar Halder, Kolkata (IN); Badri Ramamurthi, Los Gatos, CA (US)

(21) Appl. No.: 19/341,559

(22) Filed: Sep. 26, 2025

Related U.S. Application Data
(60) Provisional application No. 63/711,052, filed on Oct. 23, 2024.

(51) Int. Cl. C23C 16/455; C23C 16/44; C23C 16/54; F16K 3/02; F16K 3/314

(52) U.S. Cl. CPC C23C 16/45519; C23C 16/4409; C23C 16/54; F16K 3/0227; F16K 3/314

(57) ABSTRACT

A slit valve assembly includes a housing having an opening in a wall of the housing and through which a substate is to be transferred. The opening includes a first side to attach to a slit tunnel. A first channel is formed adjacent to a top surface of the opening. First plurality of gas holes extend from the first channel and is oriented so as to create a first gas curtain from a pressurized gas at a first angle towards a process chamber. A second channel is formed adjacent to a bottom surface of the opening. A second plurality of gas holes extend from the second channel and is oriented so as to create a second gas curtain from the pressurized gas at a second angle towards the chamber that is to intersect with, or be offset from, the first gas curtain to protect the slit tunnel from process chemistries.

### CLAIM OF PRIORITY

The present application claims the benefit under 35 U.S.C. § 119(e) of U.S. Provisional Ser. No. 63/711,052 filed Oct. 23, 2024, which is incorporated by reference herein.

### FIELD OF THE DISCLOSURE

Embodiments of the present disclosure relate generally to the field of electronic device processing systems and methods for venting a slit valve.

### BACKGROUND OF THE DISCLOSURE

Processing systems for manufacturing integrated circuits (IC) on substrates generally include process chambers for performing various processes on substrates to form the various features and structures that make up the IC. The process chamber generally includes a slit valve for selectively sealing the chamber during processing, while facilitating entry and egress of a substrate into and out of the process chamber. The slit valve generally includes a housing having an elongated opening, often referred to as a slit valve opening, for providing the physical access to the chamber through a silt tunnel that connects the slit valve opening to the chamber. For example, the slit valve opening may be accessed to transfer a substrate from a transfer chamber, through the slit tunnel, and into the process chamber, and then back again in reverse after the substrate has been processed. The slit valve further includes a gate and a compressible sealing member that provides a seal when the gate is in a closed position, e.g., to maintain an air-tight seal in the process chamber.

However, many processes typically employed to fabricate the ICs in these process chambers (such as chemical vapor deposition (CVD), physical vapor deposition (PVD), etch processes, and the like) often result in volatile and corrosive gases in the process chamber. These corrosive gases may attack the slit tunnel and the compressible sealing member of the slit valve. For example, after a period of time of being exposed to the corrosive gases, a process side of the slit valve may be especially vulnerable to degradation due to corrosive gases passing into the tunnel during substrate processing. After an even longer period of time, the compressive sealing member may also become degraded. In addition, residue from the chamber process can build up in the process side of the slit tunnel area resulting in wafer defects from particles due to the buildup of such residue.

### SUMMARY OF THE DISCLOSURE

In certain embodiments, the instant disclosure is directed to a slit valve assembly for a processing chamber, which includes a housing having an opening disposed in a wall of the housing and through which a substate is to be transferred. In embodiments, the opening includes a first side to attach to a slit tunnel. A first channel is formed adjacent to a top surface of the opening. A first plurality of gas holes extending from the first channel and oriented so as to create a first gas curtain from the pressurized gas at a first angle towards a chamber. A second channel formed adjacent to a bottom surface of the opening. A second plurality of gas holes extending from the second channel and oriented so as to create a second gas curtain from the pressurized gas at a second angle towards the chamber that is to intersect with, or be offset from, the first gas curtain to protect the slit tunnel from process chemistries.

In certain embodiments, the instant disclosure is directed to a substrate processing system that includes a process chamber having a first opening formed in a sidewall of the process chamber, a slit tunnel having a first end attached to the first opening, and a slit valve assembly such as just described. For example, the slit valve assembly can include a housing having a second opening disposed in a wall of the housing and through which a substate is to be transferred into the process chamber. The opening includes a first side attached to a second end of the slit tunnel. A manifold can be formed in the housing around the opening to receive a pressurized gas. The manifold can include a first channel formed adjacent to a top surface of the second opening. The manifold further includes A first plurality of gas holes extending from the first channel and oriented so as to create a first gas curtain from the pressurized gas at a first angle towards the process chamber. The manifold can include a second channel formed adjacent to a bottom surface of the opening. The manifold can include a second plurality of gas holes extending from the second channel and oriented so as to create a second gas curtain from the pressurized gas at a second angle towards the process chamber that is to intersect with, or be offset from, the first gas curtain to protect the slit tunnel from process chemistries.

In certain embodiments, the instant disclosure is directed to a different-scoped valve assembly including a housing having an opening disposed in a wall of the housing and through which a substate is to be transferred, wherein the opening comprises a first side to attach to a slit tunnel of a process chamber and a second side to be sealed against a gate. In embodiments, the gate is movably coupled to the second side of the housing in a plane substantially parallel to the wall for selectively sealing the opening. In embodiments, the gate includes a front surface oriented towards the slit tunnel, a channel formed within substantially a length of the gate, the channel to receive a pressurized gas, and a plurality of gas holes extending from the channel through the front surface so as to create a gas curtain from the pressurized gas directed through the slit tunnel.

### BRIEF DESCRIPTION OF THE DRAWINGS

The present disclosure is illustrated by way of example, and not by way of limitation, in the figures of the accompanying drawings in which like references indicate similar elements. It should be noted that different references to “an” or “one” embodiment in this disclosure are not necessarily to the same embodiment, and such references mean at least one.

FIG. 1 illustrates a simplified block diagram of a substrate processing system in accordance with some embodiments of the disclosure.

FIG. 2 illustrates a perspective view of a slit valve apparatus (or assembly) in accordance with embodiments of the present disclosure.

FIG. 3 illustrates a cross-section view of a substrate processing system that employs the slit valve apparatus in accordance with embodiments of the present disclosure where the gate is in closed position.

FIG. 4 illustrates a perspective, cross-section view of the slit valve apparatus according to an embodiment without the gate being illustrated.

FIG. 5 illustrates a perspective and cross-section view, cut along a slit valve opening, according to some embodiments.

FIG. 6 illustrates a perspective view of a slit valve apparatus (or assembly) in accordance with alternative embodiments of the present disclosure in which the gas holes are formed through the gate.

FIG. 7 illustrates a front, perspective view of a gate useable in the embodiment of FIG. 6 according to at least one embodiment.

FIG. 8 illustrates a cross-section view of the gate illustrated in FIG. 7 cut through a middle along a length of the gate according to at least one embodiment.

FIG. 9 illustrates a cross-section view of the gate illustrated in FIG. 7 cut along a first plurality of gas holes formed at a top half of the gate according to an embodiment.

FIG. 10 illustrates a cross-section view of the gate illustrated in FIG. 7 cut along a second plurality of gas holes formed at a bottom half of the gate according to an embodiment.

FIG. 11 illustrates a cross-section view from a side of the slit valve apparatus (or assembly) of FIG. 6 according to some embodiments.

### DETAILED DESCRIPTION

The present disclosure provides a slit valve assembly suitable for use in a process chamber, such as in a semiconductor processing apparatus, where a slit valve and a connected slit tunnel may be exposed to a damaging environment due to, for example, corrosive gases from the process chamber. As discussed previously, the slit valve generally includes a housing having an elongated opening, often referred to as a slit valve opening, for providing the physical access to the chamber through a silt tunnel that connects the slit valve opening to the chamber. For example, the slit valve opening may be accessed to transfer a substrate from a transfer chamber, through the slit tunnel, and into the process chamber, and then back again in reverse after the substrate has been processed. To protect the slit valve and the slit tunnel from corrosive gases during and/or after substrate processing, disclosed are embodiments for creating gas curtain(s) from gas holes formed in the slit valve that exit across (or directly from) the slit valve opening. In disclosed embodiments, in protecting the slit tunnel from residue build up, as discussed, the slit valve components, including the slit valve gate, are also protected.

For example, in some embodiments, the opening is disposed in a wall of the housing through which a substate is to be transferred. The opening can include a first side to attach to the slit tunnel, a second side to be sealed against a gate, a top surface, and a bottom surface. A manifold can be formed in the housing surrounding at least two sides of the opening to receive pressurized gas. For example, the manifold can include a first channel formed adjacent to the top surface. The manifold can include a first plurality of gas holes extending from the first channel through the top surface so as to create a first gas curtain from the pressurized gas. The manifold can include a second channel formed adjacent to the bottom surface. The manifold can include a second plurality of gas holes extending from the second channel through the bottom surface so as to create a second gas curtain from the pressurized gas that is to intersect with, or be offset from, the first gas curtain to protect the slit tunnel from process chemistries.

In an alternative embodiment, the manifold is not employed as above, but instead the gas holes are formed in the gate itself. For example, the gate can include a front surface oriented towards the slit tunnel and a first channel formed within substantially a length of the gate, where the first channel receives the pressurized gas. A first plurality of gas holes can extend from the first channel through the front surface so as to create a gas curtain from the pressurized gas directed through the slit tunnel. This gate structure can be repeated at least one more time, e.g., where the first channel is formed in a top half of the gate and a second channel is formed within a bottom half of the gate. A second plurality of gas holes can extend from the second channel through the front surface so as to create a second gas curtain from the pressurized gas directed through the slit tunnel.

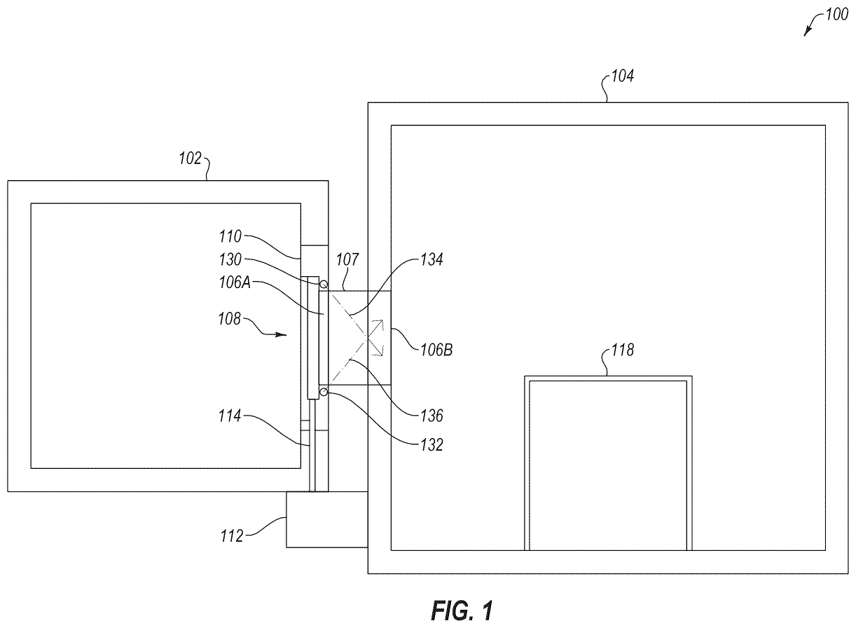

While described herein as being used in a semiconductor processing apparatus, the slit valve assembly disclosed herein may be utilized in any chamber where it is desired to prevent a corrosive environment within the chamber from attacking a slit tunnel connected to the slit valve assembly and components of the slit valve assembly. For example, FIG. 1 is a simplified block diagram illustrating an exemplary substrate processing system 100, in accordance with some embodiments. The substrate processing system 100 may be a vacuum processing system, such as a semiconductor processing apparatus. The substrate processing system 100 may include a process chamber 104 having a substrate support 118 disposed therein. Additional components typically present in a variety of process chambers (such as process gas inlets, exhaust pumps, controllers, RF generators or other plasma sources, and the like) are omitted for clarity.

Substrates are typically transferred into and out of the process chamber 104 as the substrate moves through a desired fabrication sequence. For example, a transfer chamber 102 may be coupled, via a slit tunnel 107, to the process chamber 104 to facilitate placing a substrate on, or removing the substrate from, the substrate support 118. A first opening 106A and a second opening 106B are disposed in adjacent walls of, respectively, the transfer chamber 102 and the process chamber 104, e.g., at either end of the slit tunnel 107, to facilitate transfer of a substrate into and out of the process chamber 104. A valve assembly 108 (e.g., a slit valve assembly) is disposed between the first opening 106A and the slit tunnel 107 leading to the second opening 106B, to facilitate selectively sealing the slit tunnel 107.

In embodiments, the valve assembly 108 includes a gate 110 that is movable to selectively seal the chamber 104, e.g., at the distal end of the slit tunnel 107. The gate 110 may be movable in a direction generally parallel to the plane of the opening 106 in some embodiments. An actuator 112, such as a pneumatic actuator, a hydraulic actuator, a motor, or the like, is coupled to the gate 110 via one or more rods 114. Operation of the actuator 112 thus controls the selective opening and closing of the gate 110.

In embodiments, the valve assembly 108 includes a first channel 130 in fluid communication with a first plurality of gas delivery holes at or near a top of the slit valve assembly and first opening 106A and a second channel 132 in fluid communication with a second plurality of gas delivery holes at or near a bottom of slit valve assembly and first opening 106A. The first plurality of gas delivery holes may be angled to output a first gas curtain 134 in a downward direction towards the process chamber 104, and the second plurality of gas delivery holes may be angled to output a second gas curtain 136 in an upward direction towards the process chamber 104. The first and second gas curtains 134 and 136 may intersect (or be offset from but adjacent to each other), and together may prevent process gasses and/or corrosive chemistries from the process chamber 104 from contacting the slit valve assembly.

As used herein, the singular forms “a,” “an,” and “the” include plural references unless the context clearly indicates otherwise. Thus, for example, reference to “a substrate” includes a single substrate as well as two or more substrates (or wafers), and the like.

As used herein, the term “about” in connection with a measured quantity, refers to the normal variations in that measured quantity, as expected by one of ordinary skill in the art in making the measurement and exercising a level of care commensurate with the objective of measurement and the precision of the measuring equipment. In certain embodiments, the term “about”includes the recited number ±10%, such that “about 10”would include from 9 to 11.

Recitation of ranges of values herein are merely intended to serve as a shorthand method of referring individually to each separate value falling within the range, unless otherwise indicated herein, and each separate value is incorporated into the specification as if it were individually recited herein. All methods described herein can be performed in any suitable order unless otherwise indicated herein or otherwise clearly contradicted by context. The use of any and all examples, or exemplary language (e.g., “such as”) provided herein, is intended merely to illuminate certain materials and methods and does not pose a limitation on scope. No language in the specification should be construed as indicating any non-claimed element as essential to the practice of the disclosed materials and methods.

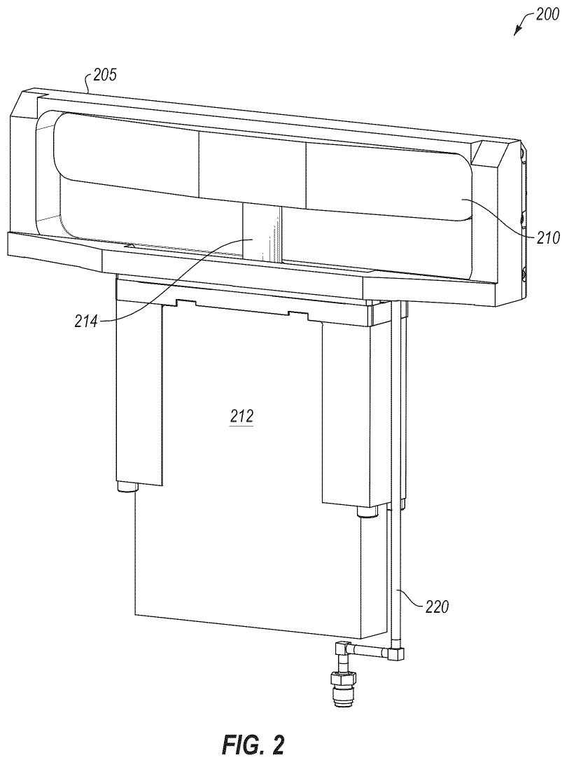

FIG. 2 illustrates a perspective view of a slit valve apparatus 200 (or assembly) in accordance with embodiments of the present disclosure. In various embodiments, the slit valve apparatus 200 includes a housing 205, a gate 210 that moves up and down within the housing 205, an actuator 212, and a rod 214 coupled between the actuator 212 and the gate 210. In some embodiments, the slit valve apparatus 200 is adapted for use as the valve assembly 108 (FIG. 1). The slit valve apparatus 200 can further include a gas delivery line 220 to provide gas to the housing 205 for purposes that will be apparent.

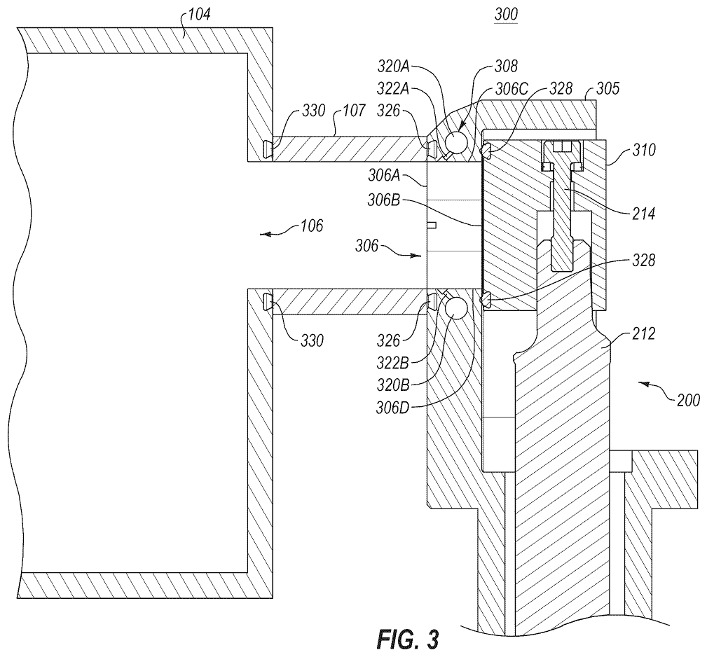

FIG. 3 illustrates a cross-section view of a substrate processing system 300 that employs the slit valve apparatus 200 in accordance with embodiments of the present disclosure where the gate is in closed position. In at least some embodiments, the substrate processing system 300 includes the process chamber 104, a slit tunnel 107 coupled to the process chamber 104 (see FIG. 1), and the slit valve apparatus 200 coupled to an opposite end of the slit tunnel 107. More specifically, the process chamber 104 can include a first opening 106 formed in a sidewall of the processing chamber 104. The slit tunnel 107 can include a first end attached to the first opening 106A. The slit valve apparatus 200 can be configured to seal closed a proximate end of the slit tunnel 107, as will be described in more detail.

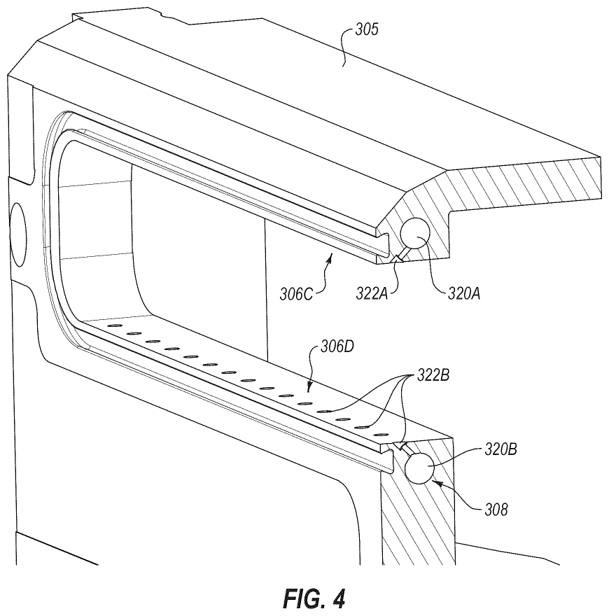

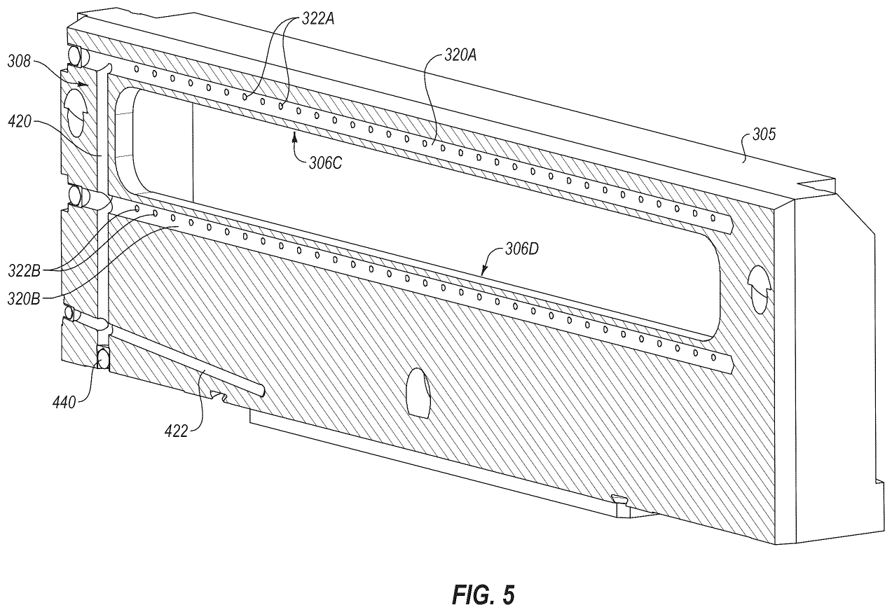

In some embodiments, the slit valve apparatus 200 (or assembly) includes a housing 305, a gate 310, the actuator 212, and the rod 214, the latter two of which were discussed with reference to FIG. 2. In embodiments, the housing 305 includes a second opening 306 disposed in a wall of the housing 305 and through which a substate (or wafer) is to be transferred. The second opening can include a first side 306A to attach to the slit tunnel 107, a second side 306B to be sealed against the gate 310, a top surface 306C, and a bottom surface 306D. FIG. 4 illustrates a perspective, cross-section view of the slit valve apparatus 200 according to an embodiment without the gate 310 being illustrated. FIG. 5 illustrates a perspective and cross-section view, cut along the second opening 306, according to some embodiments. In embodiments, the gate 310 is movably coupled to the second side 306B of the housing in a plane substantially parallel to the wall of the housing 305 for selectively sealing the second opening 306. The actuator 212 can be attached to the gate 310 to cause the gate 310 to move.

In some embodiments, the slit valve apparatus 200 includes a first O-ring 326 (or other seal) embedded within the first side 306A and around the second opening 306, to seal the housing 305 at the second opening 306 to a proximal end of the slit tunnel 107. The slit valve apparatus 200 can further include a second O-ring 328 (or other seal) embedded within a surface of the gate 310 to selectively seal the gate 310 to the second opening 306 of the housing 305 as the gate 310 is moved up and down. Finally, the substrate processing system 300 can further include a third O-ring 330 (or other seal) embedded within the process chamber 104, around the first opening 106, to seal the process chamber 104 to a distal end of the slit tunnel 107.

With additional reference to FIGS. 4-5, in some embodiments, the slit valve apparatus 200 includes a manifold 308 formed in the housing 305 around the opening 306 to receive a pressurized gas, e.g., from the gas delivery line 220. In at least one embodiment, the manifold 308 includes a first channel 320A formed adjacent to the top surface 306C and a first plurality of gas holes 322A extending from the first channel 320A through the top surface 306C and oriented so as to create the first gas curtain 134 from the pressurized gas. The manifold 308 can further include a second channel 320B formed adjacent to the bottom surface 306D and a second plurality of gas holes 322B extending from the second channel 320B through the bottom surface 306D and oriented so as to create the second gas curtain 136 from the pressurized gas that is to intersect with the first gas curtain. The intersection of the first gas curtain with the second gas curtain can protect the slit tunnel 107 from process chemistries generated within the process chamber 104. In other embodiments, the first gas curtain 134 is offset from the second gas curtain 136, e.g., passing adjacent to each other but still able to cover protection of the slit valve tunnel 107.

In some embodiments, a first diameter of the first channel 320A differs from a second diameter of the second channel 320B, although the diameters can also be the same size. Further, in embodiments, a first diameter of at least some of the first plurality of gas holes 322A differs from a second diameter of at least some of the second plurality of gas holes 322B, although the diameters may also be the same. The spacing between gas holes of the first plurality of gas holes 322A and/or the second plurality of gas holes 322B can also vary. These variations in channel and gas holes sizes and spacing can be customized to improve or change gas flow uniformity to improve gas flow to particular problematic areas in or around the process side of the slit valve tunnel 107.

In disclosed embodiments, the first plurality of gas holes 322A extend at a first angle with respect to the top surface 306C so that the first gas curtain exits the first side 306A across the second opening 306 towards a bottom of the slit tunnel 107. Further, the second plurality of gas holes 322B extend at a second angle with respect to the bottom surface 306D so that the second gas curtain exits the first side 306A across the second opening 306 towards a top of the slit tunnel 107, according to illustrated embodiments. In some embodiments, the first angle matches the second angle, meaning that the first and second gas curtains can intersect, or be offset from, at approximately right angles to each other.

In some embodiments, with reference to FIG. 5, the manifold 308 further includes at least a third channel 420 that connects the first channel 320A to the second channel 320B and extends to a gas line (e.g., the gas delivery line 220 of FIG. 2) attached to an exterior of the housing 305, e.g., where the gas line supplies the pressurized gas. In some embodiments, the third channel 420 exits the housing 305 at an aperture 440 adapted to receive the gas line. Further, the manifold 308 can further include a fourth channel 422 that intersects with the third channel 420 to provide additional gas inlet space as well as an exit for the pressurized gas (out of the side of the housing 305) when gas is to be diverted from exiting the plurality of gas holes.

In some embodiments, although not specifically illustrated, each of the first plurality of gas holes 322A and the second plurality of gas holes 322B include a first set of gas holes located closest to the third channel 420 and a second set of gas holes located beyond the first set of holes, where gas holes of the second set have a larger diameter than gas holes of the first set. For example, sets of gas holes positioned farther from the third channel 420 away from the third channel 420 can progressively get bigger, enabling a relatively constant gas flow across the first and second gas curtains without delay.

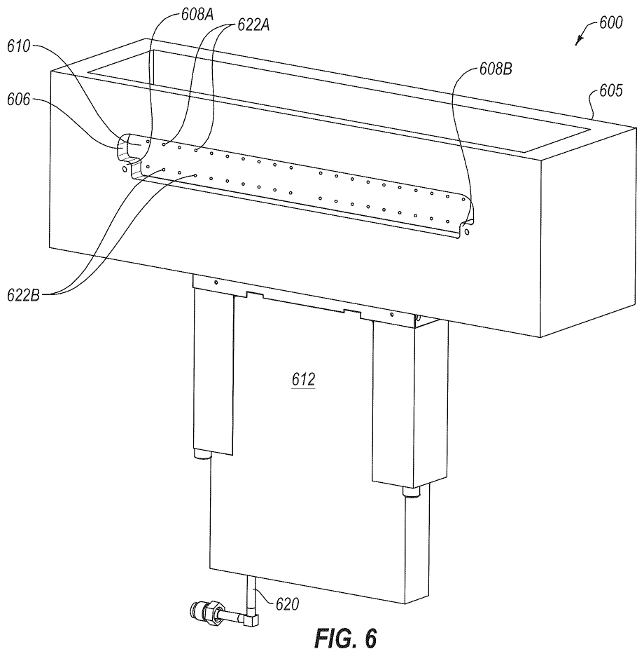

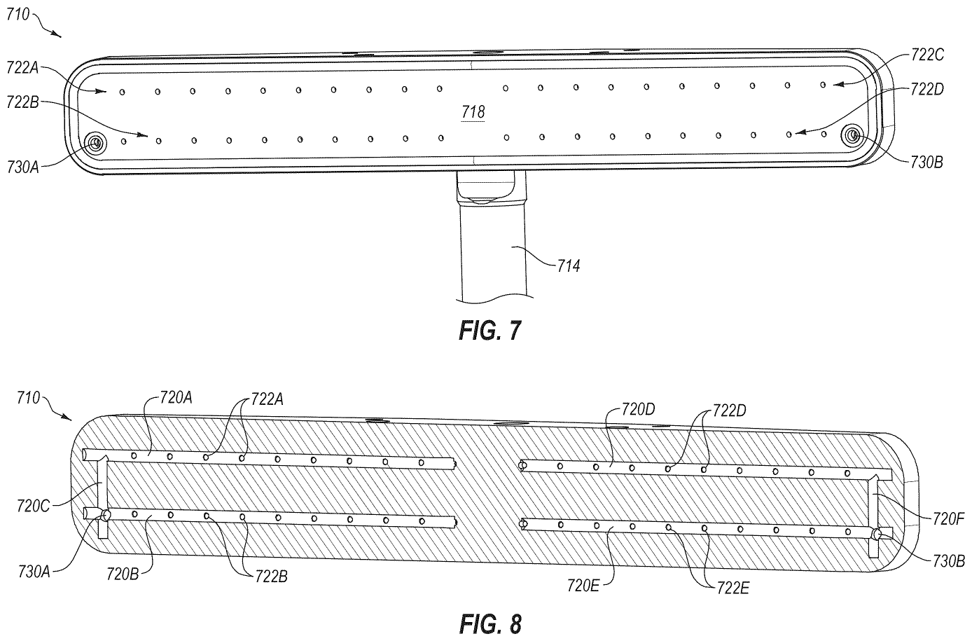

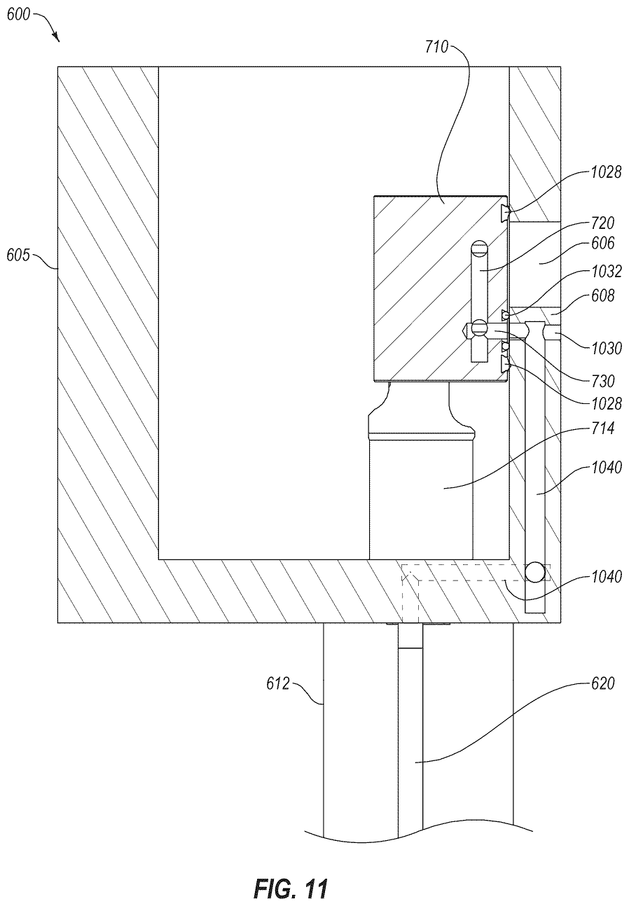

FIG. 6 illustrates a perspective view of a slit valve apparatus 600 (or assembly) in accordance with alternative embodiments of the present disclosure in which the gas holes are formed through the gate. For example, the slit valve apparatus 200 of FIGS. 2-5 could be replaced with the slit valve apparatus 600. In embodiments, the slit valve apparatus 600 includes a housing 605, a gate 610 that moves up and down within the housing 605, an actuator 612, and a rod 714 (see FIG. 7) coupled between the actuator 612 and the gate 610. In some embodiments, the slit valve apparatus 600 is adapted for use as the valve assembly 108 (FIG. 1). The slit valve apparatus 600 can further include a gas delivery line 620 to provide gas to the housing 605 and the gate 610, as will be explained in more detail with reference to FIG. 11.

In some embodiments, the housing 605 includes an opening 606 disposed in a wall of the housing 605 and through which a substate is to be transferred. The opening 606 can include a first side to attach to a slit tunnel of a process chamber and a second side to be sealed against the gate 610, as was discussed with reference to FIG. 1 and FIG. 2. The gate 610 can be movably coupled to the second side of the housing 605 in a plane substantially parallel to the wall for selectively sealing the opening 606.

In at least some embodiments, the wall of the housing 605 includes a first tab 608A and a second tab 608B that protrude into the opening 606 to carry pressurized gas. For example, the pressurized gas can be carried through channels of the housing 605 and the gate 610 that ultimately exits through a plurality of gas holes formed in the gate 610. For example, the gas holes can include a first plurality of gas holes 622A formed within a top half of the gate 610 and a second plurality of gas holes 622B formed within a bottom half of the gate 610 to force the pressurized gas out within gas curtains that protect the slit tunnel 107 from corrosive gases.

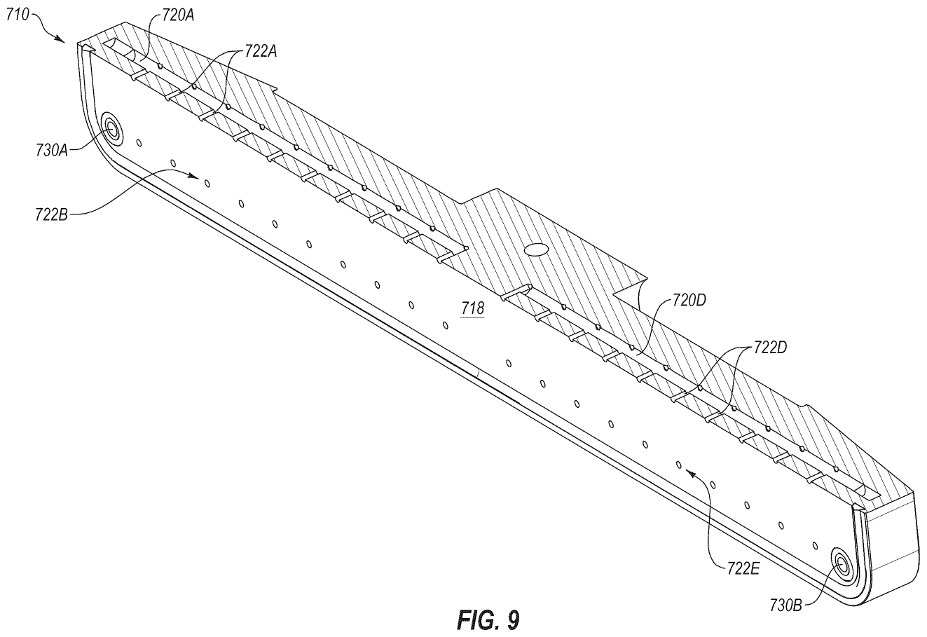

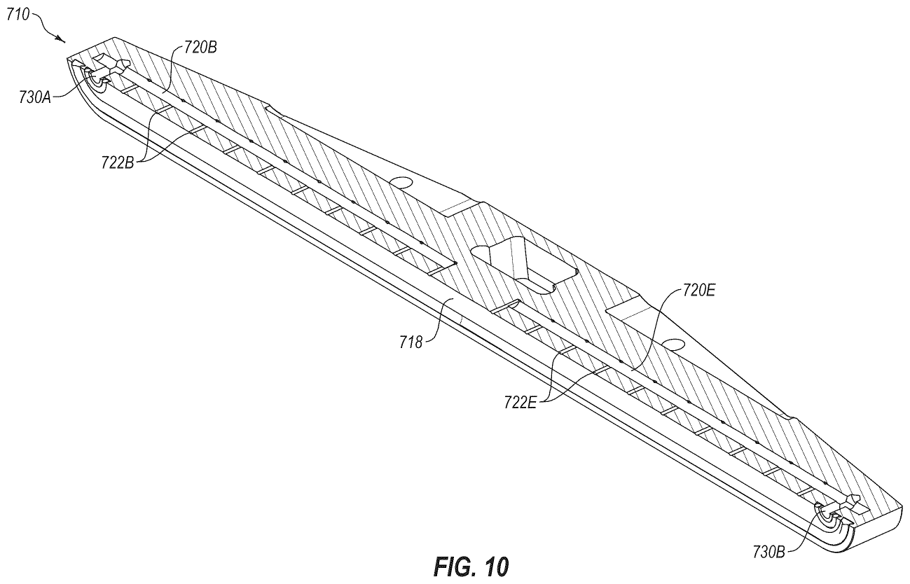

FIG. 7 illustrates a front, perspective view of a gate 710 useable in the embodiment of FIG. 6 according to at least one embodiment. For example, the gate 710 could be the gate 610 illustrated in FIG. 6 in some embodiments. FIG. 8 illustrates a cross-section view of the gate 710 illustrated in FIG. 7 cut through a middle along a length of the gate 710 according to at least one embodiment. FIG. 9 illustrates a cross-section view of the gate 710 illustrated in FIG. 7 cut along a first plurality of gas holes 722A formed at a top half of the gate 710 according to an embodiment. FIG. 10 illustrates a cross-section view of the gate illustrated in FIG. 7 cut along a second plurality of gas holes 722B formed at a bottom half of the gate 710 according to an embodiment.

In embodiments, the gate 710 includes a front surface 718 oriented towards the slit tunnel 107 (FIG. 1) and a channel (or multiple channels), formed within substantially a length of the gate 710, to receive a pressurized gas. The gate 710 can further include a plurality of gas holes extending from the channel (or multiple channels) through the front surface 718 so as to create a gas curtain from the pressurized gas directed through the slit tunnel 107. In some embodiments, the plurality of gas holes are formed perpendicular to the channel. In some embodiments, the plurality of gas holes are oriented orthogonally with respect to the front surface 718. In other embodiments, at least some of the plurality of holes are oriented at one or more angles with respect to the front surface 718.

More specifically, the multiple channels can include a first channel 720A formed in a top half of the gate 710 and the plurality of gas holes can include the first plurality of gas holes 722A extending from the first channel 720A through the front surface 718 so as to create a first gas curtain from the pressurized gas directed through the slit tunnel 107. Additionally, the multiple channels can include a second channel 720B formed within a bottom half of the gate 710 and the plurality of gas holes can include the second plurality of gas holes 722B extending from the second channel 720B through the front surface 718 so as to create a second gas curtain from the pressurized gas directed through the slit tunnel 107. In embodiments, a third channel 720C is formed within the gate 710 that connects the first channel 720A to the second channel 720B. In some embodiments, the first channel 720A and the second channel 720B extend substantially the length of the gate 710 and the first and second gas curtains merge to provide a single pressurized gas front to protect the slit tunnel 107 and the slit valve apparatus 600 from corrosive gases.

In other embodiments, as illustrated, the first channel 720A and the second channel 720B extend only partially (e.g., halfway) along the length of the gate 710 so as to create a smaller, but stronger, gas curtain from each of the first plurality of holes 722A and the second plurality of holes 722B, respectively. In such embodiments, the gate 710 can further include a fourth channel 720D formed in the top half of the gate 710 (e.g., after a break in the first channel 720A) and a third plurality of gas holes 722D extending from the fourth channel 720D through the front surface 718 so as to create a third gas curtain from the pressurized gas directed through the slit tunnel 107. The gate 710 can further include a fifth channel 720E formed within the bottom half of the gate 710 (e.g., after a break in the second channel 720B) and a fourth plurality of gas holes 722E extending from the fifth channel 720E through the front surface 718 so as to create a fourth gas curtain from the pressurized gas directed through the slit tunnel 107. In embodiments, a sixth channel 720F is formed within the gate 710 that connects the fourth channel 720D to the fifth channel 720E.

In some embodiments, diameters of the first channel 720A, the second channel 720B, the third channel 720C, the fourth channel 720D, the fifth channel 720E, and the sixth channel 720F can be similar or different from each other, and thus can vary in size. Further, diameters of the plurality of gas holes in each of these channels can also be the same or differ from each other and spacing between the gas holes can also vary. These variations in channel and gas holes sizes and spacing can be customized to improve or change gas flow uniformity to improve gas flow to particular problematic areas in or around the process side of the slit valve tunnel 107.

In some embodiments, the gate 710 includes a first gas inlet channel 730A formed in the front surface 718 and that connects to the third channel 720C. The first gas inlet channel 730A can also optionally connect to the second channel 720B, as illustrated. The gate 710 can further include a second gas inlet channel 730B formed in the front surface 718 and that connects to the sixth channel 720F. The second gas inlet channel 730B can also optionally connect to the fifth channel 720E, as illustrated. In this way, gas flowing in from the housing 605 (see FIG. 11) can flow into the various channels formed within the gate 710 to be forcefully expelled, as gas curtains, through the plurality of gas holes formed through the front surface 718 of the gate 710.

FIG. 11 illustrates a cross-section view from a side of the slit valve apparatus 600 (or assembly) of FIG. 6 according to some embodiments. In some embodiments, as was discussed, the wall of the housing 605 includes a tab 608 protruding (or that protrudes) within the opening 606 of the housing, where the tab 608 could be the first tab 608A or the second tab 608B (see FIG. 6). The tab 608 can include a gas outlet channel 1030 formed substantially perpendicular to a channel 720 (e.g., the first channel 720A or the second channel 720B) and at least partway through a thickness of the tab 608. In some embodiments, the gas output channel 1030 is formed through the entirety of the thickness of the tab 608, so as to eject gas with the gas curtains, but this is not required. In embodiments, the gate 710 includes a gas inlet channel 730 (e.g., the first gas inlet channel 730A or the second gas inlet channel 730B) connected to the channel 720 that corresponds to the gas outlet channel 1030 when the gate 710 is closed. In at least one embodiment, an O-ring 1028 (or other seal) is embedded within the gate 710 so the gate an be sealingly closed against the housing 605 when in moved to a closed (or up) position.

In some embodiments, the slit valve apparatus 600 includes a gas flow channel 1040 formed within the housing 605 between a bottom of the housing and the gas outlet channel 1030. In embodiments, a gas line, such as the gas delivery line 620, is attached to the gas flow channel 1040. In embodiments, a sealing ring 1032 is positioned around the gas inlet channel 730 and attached to the front surface 718 of the gate 710, e.g., so that the interface between the gas outlet channel 1030 and the gas inlet channel 730 is sealed against the pressurized gas. The flow rate of the gas can be around 1000-2000 standard cubic centimeters per minute (sccm) depending on the application. In one embodiments, the flow rate of the gas is 1500 sccm, for example.

In the foregoing description, numerous specific details are set forth, such as specific materials, dimensions, processes parameters, etc., to provide a thorough understanding of the present disclosure. The particular features, structures, materials, or characteristics may be combined in any suitable manner in one or more embodiments. The words “example” or “exemplary” are used herein to mean serving as an example, instance, or illustration. Any aspect or design described herein as “example” or “exemplary” is not necessarily to be construed as preferred or advantageous over other aspects or designs. Rather, use of the words “example” or “exemplary” is simply intended to present concepts in a concrete fashion. As used in this application, the term “or” is intended to mean an inclusive “or” rather than an exclusive “or”. That is, unless specified otherwise, or clear from context, “X includes A or B” is intended to mean any of the natural inclusive permutations. That is, if X includes A; X includes B; or X includes both A and B, then “X includes A or B” is satisfied under any of the foregoing instances. Reference throughout this specification to “an embodiment”, “certain embodiments”, or “one embodiment” means that a particular feature, structure, or characteristic described in connection with the embodiment is included in at least one embodiment. Thus, the appearances of the phrase “an embodiment”, “certain embodiments”, or “one embodiment” in various places throughout this specification are not necessarily all referring to the same embodiment.

Embodiments of the present disclosure have been described with reference to specific exemplary embodiments thereof. The specification and drawings are, accordingly, to be regarded in an illustrative rather than a restrictive sense. Various modifications of the disclosure in addition to those shown and described herein will become apparent to those skilled in the art and are intended to fall within the scope of the appended claims.

We claim:

1. A slit valve assembly for a processing chamber, comprising:
a housing having an opening in a wall of the housing and through which a substate is to be transferred, wherein the opening comprises a first side to attach to a slit tunnel;
a first channel formed adjacent to a top surface of the opening;
a first plurality of gas holes extending from the first channel and oriented so as to create a first gas curtain from a pressurized gas at a first angle towards a process chamber;
a second channel formed adjacent to a bottom surface of the opening; and
a second plurality of gas holes extending from the second channel and oriented so as to create a second gas curtain from the pressurized gas at a second angle towards the chamber that is to intersect with, or be offset from, the first gas curtain to protect the slit tunnel from process chemistries.

2. The slit valve assembly of claim 1, wherein
the first plurality of gas holes extend at the first angle through the top surface so that the first gas curtain exits the first side across the opening towards a bottom of the slit tunnel; and
the second plurality of gas holes extend at the second angle through the bottom surface so that the second gas curtain exits the first side across the opening towards a top of the slit tunnel.

3. The slit valve assembly of claim 1, wherein the first angle matches the second angle.

4. The slit valve assembly of claim 1, further comprising at least a third channel that connects the first channel to the second channel and extends to a gas line attached to an exterior of the housing, and wherein the gas line supplies the pressurized gas.

5. The slit valve assembly of claim 4, wherein each of the first plurality of gas holes and the second plurality of gas holes comprise a first set of gas holes located closest to the third channel and a second set of gas holes located beyond the first set of holes, and wherein gas holes of the second set have a larger diameter than gas holes of the first set.

6. The slit valve assembly of claim 1, further comprising a gate movably coupled to a second side of the housing in a plane substantially parallel to the wall of the housing for selectively sealing the opening.

7. The slit valve assembly of claim 6, further comprising an O-ring embedded within a surface of the gate to selectively seal the gate to the opening of the housing.

8. A substrate processing system comprising:
a process chamber having a first opening formed in a sidewall of the process chamber;
a slit tunnel having a first end attached to the first opening; and
a slit valve assembly comprising:
a housing having a second opening in a wall of the housing and through which a substate is to be transferred into the process chamber, wherein the second opening comprises a first side attached to a second end of the slit tunnel; and
a manifold formed in the housing around the second opening to receive a pressurized gas, wherein the manifold comprises:
a first channel formed adjacent to a top surface of the second opening;
a first plurality of gas holes extending from the first channel and oriented so as to create a first gas curtain from the pressurized gas at a first angle towards the process chamber;
a second channel formed adjacent to a bottom surface of the opening; and
a second plurality of gas holes extending from the second channel and oriented so as to create a second gas curtain from the pressurized gas at a second angle towards the process chamber that is to intersect with, or be offset from, the first gas curtain to protect the slit tunnel from process chemistries.

9. The substrate processing system of claim 8, wherein:
the first plurality of gas holes extend at the first angle through the top surface so that the first gas curtain exits the first side across the opening towards a bottom of the slit tunnel; and
the second plurality of gas holes extend at the second angle through the bottom surface so that the second gas curtain exits the first side across the opening towards a top of the slit tunnel.

10. The substrate processing system of claim 8, wherein a first diameter of the first channel differs from a second diameter of the second channel.

11. The substrate processing system of claim 8, wherein the manifold further comprises at least a third channel that connects the first channel to the second channel and extends to a gas line attached to an exterior of the housing, and wherein the gas line supplies the pressurized gas.

12. The substrate processing system of claim 8, wherein a first diameter of at least some of the first plurality of gas holes differs from a second diameter of at least some of the second plurality of gas holes.

13. The substrate processing system of claim 8, further comprising:
a gate movably coupled to the second side of the housing in a plane substantially parallel to the wall of the housing for selectively sealing the opening; and
an actuator attached to the gate to cause the gate to move.

14. The substrate processing system of claim 13, further comprising an O-ring embedded within a surface of the gate to selectively seal the gate to the second opening of the housing.

15. A valve assembly for a processing chamber comprising:
a housing having an opening disposed in a wall of the housing and through which a substate is to be transferred, wherein the opening comprises a first side to attach to a slit tunnel of a process chamber and a second side to be sealed against a gate; and
the gate movably coupled to the second side of the housing in a plane substantially parallel to the wall for selectively sealing the opening, wherein the gate comprises:
a front surface oriented towards the slit tunnel;
a channel formed within substantially a length of the gate, the channel to receive a pressurized gas; and
a plurality of gas holes extending from the channel through the front surface so as to create a gas curtain from the pressurized gas directed through the slit tunnel.

16. The valve assembly of claim 15, wherein the plurality of gas holes are formed perpendicular to the channel.

17. The valve assembly of claim 15, wherein:
the wall of the housing comprises a tab protruding within the opening of the housing, the tab comprising a gas outlet channel formed substantially perpendicular to the channel and at least partway through a thickness of the tab; and
the gate comprises a gas inlet channel connected to the channel that corresponds to the gas outlet channel when the gate is closed.

18. The valve assembly of claim 17, further comprising:
a gas flow channel formed within the housing between a bottom of the housing and the gas outlet channel;
a gas line attached to the gas flow channel; and
a sealing ring positioned around the gas inlet channel and attached to the front surface of the gate.

19. The valve assembly of claim 15, wherein the channel is a first channel formed in a top half of the gate and the plurality of gas holes are a first plurality of gas holes, further comprising:
a second channel formed within a bottom half of the gate; and
a second plurality of gas holes extending from the second channel through the front surface so as to create a second gas curtain from the pressurized gas directed through the slit tunnel.

20. The valve assembly of claim 19, further comprising:
a tab of the wall of the housing that protrudes within the opening and comprises a gas outlet channel formed substantially perpendicular to the second channel and partway through a thickness of the tab;
a third channel formed within the gate that connects the first channel to the second channel;
a gas inlet channel formed within the gate that corresponds to the gas outlet channel when the gate is closed, wherein the gas inlet channel connects with one of the second channel or the third channel; and
a sealing ring positioned around the gas inlet channel and attached to the front surface of the gate.
